(19) United States
(12) Patent Application Publication
(10) Pub. No.: US 2010/0149867 A1
(43) Pub. Date: Jun. 17, 2010

(54) NONVOLATILE SEMICONDUCTOR MEMORY DEVICE

(76) Inventors: Hiroaki Tanaka, Hadano-shi (JP); Hitoshi Shiga, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/552,671

(22) Filed: Sep. 2, 2009

(30) Foreign Application Priority Data
Dec. 12, 2008 (JP) 2008-317001
Jul. 6, 2009 (JP) 2009-159979

(51) Int. Cl. G11C 16/04

(52) U.S. Cl. 365/185.03; 365/185.18

(57) ABSTRACT

A nonvolatile semiconductor memory device includes a nonvolatile memory which includes a block having a plurality of memory cell groups, each of the memory cell groups being electrically connected to a plurality of bit lines and electrically connected to a common word line, each memory cell being recordable of a plurality of bits, a first register which stores information obtained by correcting first data to be written to a first word line, and a control circuit which sets a set potential in the first register and writes the bits to a write target first memory cell at a time using the information in the first register, the set potential being obtained by subtracting, from a target potential to be finally set in the first memory cell, a potential increase which is generated by setting a potential in an unwritten second memory cell adjacent to the first memory cell.

### CROSS-REFERENCE TO RELATED APPLICATIONS

This application is based upon and claims the benefit of priority from prior Japanese Patent Applications No. 2008-317001, filed Dec. 12, 2008; and No. 2009-159979, filed Jul. 6, 2009, the entire contents of both of which are incorporated herein by reference.

### BACKGROUND OF THE INVENTION

1. Field of the Invention

The present invention relates to a nonvolatile semiconductor memory device comprising an electrically rewritable memory cell.

2. Description of the Related Art

A NAND flash memory is known as an electrically rewritable nonvolatile semiconductor memory. When data is recorded in the NAND flash memory, the data is typically recorded from one end of a block to the other in the order of word lines. Here, the data is recorded in two separate steps for even bit lines and odd bit lines regarding one word line so that interference between bit lines can be constrained.

If a given memory cell in the NAND flash memory is charged, the potentials of floating gate electrodes in previously recorded adjacent cells vary due to a coupling effect from the given memory cell. As a result, information originally recorded in the adjacent cells disadvantageously changes (coupling effect). This disadvantage is more serious in a multilevel cell (MLC) type flash memory in which the potential width effective for information to be recorded is small.

In order to constrain the coupling effect, in the MLC type flash memory, target potentials for a plurality of pieces of information to be recorded in the memory cells are allocated so that the intervals may be gradually smaller. Further, in one scheme that is used, roughly set bits are first written, and all of the adjacent bits are roughly set, and then finely set bits are sequentially overlaid (Jpn. Pat. Appln. KOKAI Publication No. 2004-192789). According to this scheme, when a potential corresponding to a certain bit is set, the potential is overlaid so that a coupling effect resulting from the previously set rough potentials is corrected at the same time. Thus, the variations of the potentials remaining at the end of recording can be as low as a coupling effect associated with potential variations produced when the last bit is written.

However, if the potentials of the memory cells are more closely connected together, the coupling effect resulting from the rough setting cannot be completely absorbed at the subsequent finer potential setting. Thus, a correct potential setting is precluded, or potential variations of the adjacent cells generated by writing the last bit exceed the threshold value of potential recognition. As a result, written data might differ from data that can be read. Another disadvantage is that a writing speed decreases because data is written to the memory cells at separate times.

### BRIEF SUMMARY OF THE INVENTION

According to an aspect of the present invention, there is provided a nonvolatile semiconductor memory device comprising: a nonvolatile memory which includes a block having a plurality of memory cell groups, each of the memory cell groups being electrically connected to a plurality of bit lines and electrically connected to a common word line, each memory cell being recordable of a plurality of bits; a first register which stores information obtained by correcting first data to be written to a first word line; and a control circuit which sets a set potential in the first register and writes the bits to a write target first memory cell at a time using the information in the first register, the set potential being obtained by subtracting, from a target potential to be finally set in the first memory cell, a potential increase which is generated by setting a potential in an unwritten second memory cell adjacent to the first memory cell.

A nonvolatile semiconductor memory device comprising: a nonvolatile memory which includes a block having a plurality of memory cell groups, each of the memory cell groups being electrically connected to a plurality of bit lines and electrically connected to a common word line, each memory cell being recordable of a plurality of bits; a first register which stores information obtained by correcting first data to be written to a first word line; and a control circuit which performs writing separately for even bit lines and odd bit lines, sets a set potential in the first register, and writes the bits to a write target first memory cell at a time using the information in the first register, the set potential being obtained by subtracting, from a target potential to be finally set in the first memory cell, a potential increase which is generated by setting a potential in an unwritten second memory cell adjacent to the first memory cell.

### BRIEF DESCRIPTION OF THE SEVERAL VIEWS OF THE DRAWING

FIG. 1 is a schematic diagram of a memory cell array;

FIG. 2 is a block diagram showing the configuration of a nonvolatile semiconductor memory device 1 according to a first embodiment;

FIG. 3 is a diagram showing one example of a memory cell array 22 shown in FIG. 2;

FIG. 4 is a sectional view showing the configuration of one NAND string;

FIG. 5 is a schematic diagram showing the configurations of work registers;

FIG. 6A is a flowchart showing the overall operation of the nonvolatile semiconductor memory device 1;

FIG. 6B is a flowchart showing the overall operation of the nonvolatile semiconductor memory device 1 following FIG. 6A;

FIG. 7 is a flowchart showing a data flash operation;

FIG. 8 is a flowchart showing processing for storing received data into a data register;

FIG. 9A is a flowchart showing processing for writing into a word line;

FIG. 9B is a flowchart showing processing for writing into the word line following FIG. 9A;

FIG. 10 is a table showing one example of a target potential corresponding to recording data;

FIG. 11 is a flowchart showing processing for setting potentials for bit lines;

FIG. 12A is a flowchart showing write check processing;

FIG. 12B is a flowchart showing the write check processing following FIG. 12A;

FIG. 13 is a graph explaining specific examples of potential setting for the bit lines and the write check;

FIG. 14A is a flowchart showing processing for writing into a word line according to a third embodiment;

FIG. 14B is a flowchart showing processing for writing into the word line following FIG. 14A;

FIG. 15 is a flowchart showing processing for calculating a set potential of a memory cell;

FIG. 16 is a flowchart showing processing for writing into a word line according to a fourth embodiment;

FIG. 17A is a flowchart showing processing for writing into a word line according to a fifth embodiment;

FIG. 17B is a flowchart showing processing for writing into the word line following FIG. 17A;

FIG. 18A is a flowchart showing write check processing;

FIG. 18B is a flowchart showing the write check processing following FIG. 18A; and

FIG. 19 is a view showing a conversion table for set potentials.

### DETAILED DESCRIPTION OF THE INVENTION

The embodiments of the present invention will be described hereinafter with reference to the accompanying drawings. In the description which follows, the same or functionally equivalent elements are denoted by the same reference numerals, to thereby simplify the description.

Information is recorded (written) to a NAND flash memory by changing the potential of a charge storage layer (floating gate electrode). However, this potential cannot be directly known from the outside. Instead, this potential is known from the intensity of a voltage applied to a control gate electrode which is necessary to offset the potential of the floating gate electrode to change a channel from a shut state to a conducting state. Therefore, in the following description, a cell potential means the potential of the control gate electrode necessary to change the channel of the memory cell to a conducting state. In general, there is a proportional relationship between the potential of the floating gate electrode and the cell potential if two potentials in an erased state are origins.

In the present invention, writing to each memory cell is completed by one writing process. Here, a coupling effect of adjacent cells is predicted, and a cell potential from which a corresponding amount is subtracted is set to offset the coupling effect.

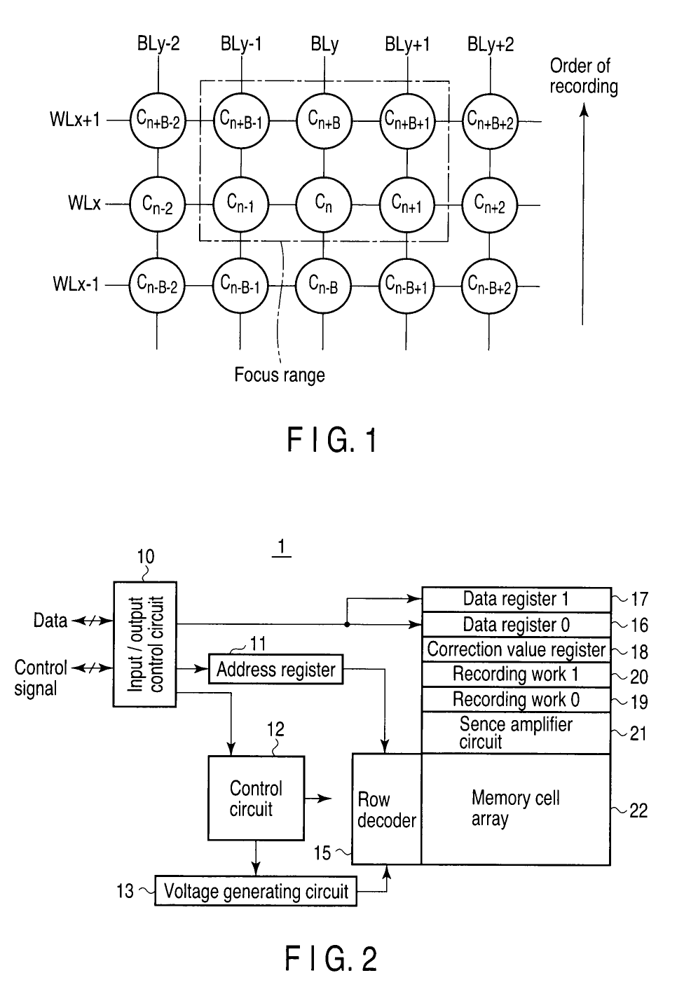

As shown in FIG. 1, adjacent cells in which bit lines adjoin a focus memory cell Cₙ on the same word line WLx are Cₙ₋₁, Cₙ₊₁, while adjacent cells in which word lines adjoin on the same bit line BLy are C_{n-B}, C_{n+B}. “B” indicates the number of bit lines.

When data is written to an adjacent unwritten cell on the same bit line as the memory cell Cₙ and on an adjacent word line, the ratio of the influence of a resulting potential change on the potential of the memory cell Cₙ is “Yw”. When data is written to an adjacent unwritten cell on the same word line as the memory cell Cₙ and on an adjacent bit line, the ratio of the influence of a resulting potential change on the potential of the memory cell Cₙ is “Yb”. When data is written to an oblique unwritten cell in which both a word line and a bit line are adjacent to the memory cell Cₙ, the ratio of the influence of a resulting potential change on the potential of the memory cell Cₙ is “Yc”. A potential (target potential) to be finally set in the memory cell Cₙ is indicated by “Eₙ”. A potential (set potential) to actually charge the memory cell Cₙ is indicated by Vn. However, the target potential and the set potential have values based on the potential of the erased memory cell.

When information is written to the memory cells connected to the same word line, writing is performed first for the memory cells connected to even bit lines, and then performed for the memory cells connected to odd bit lines. Because a memory cell receives the coupling effect only from adjacent unwritten memory cells, the set potentials of the memory cells on the even bit lines to be first written can be represented by Expression (1):

Vₙ=Eₙ−(Eₙ₋₁+Eₙ₊₁)Yb−E_{n+B}Yw−(E_{n+B-1}+E_{n+B+}1)Yc− (1)

The set potentials of the odd cells to which information is written later can be represented by Expression (2):

Vₙ=Eₙ−E_{n+B}Yw−(E_{n+B-1}+E_{n+B+1})Yc− (2)

If the potential based on the above expression is correctly set, the final potential of each memory cell can be a value closer to an expected value only by recording information in each memory cell one time.

### First Embodiment

[1. Configuration of Nonvolatile Semiconductor Memory Device 1]

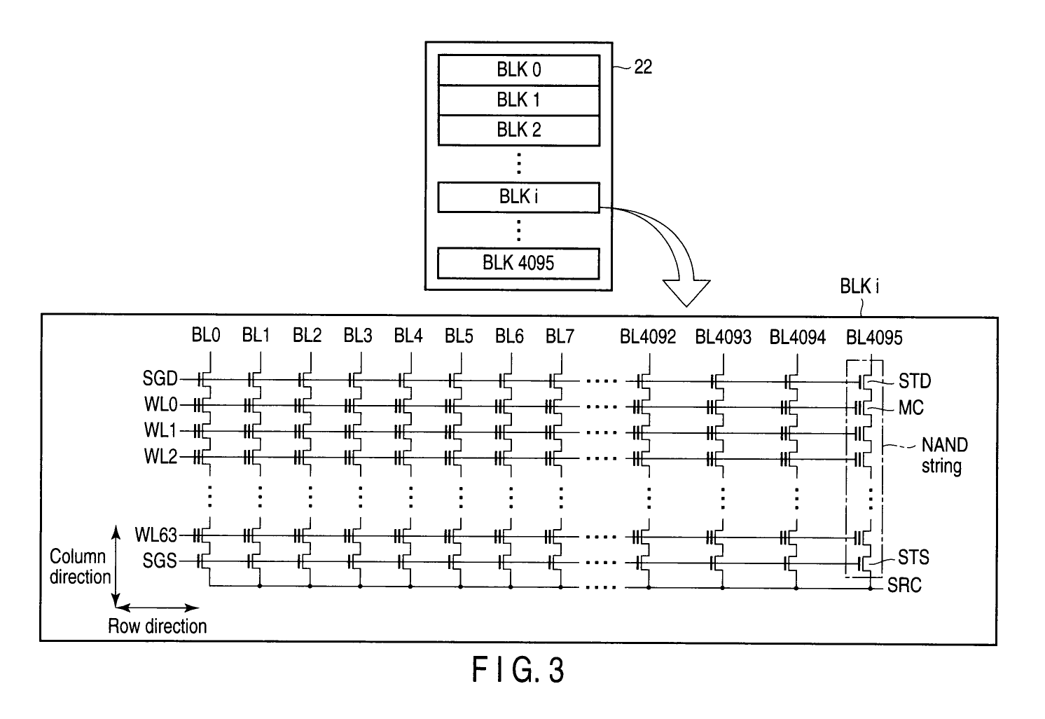

FIG. 2 is a block diagram showing the configuration of a nonvolatile semiconductor memory device 1 according to a first embodiment of the present invention. While the nonvolatile semiconductor memory device 1 has both data writing and reading functions, the following description concerns writing. Reading can be achieved by using a conventionally used technique as it is.

The nonvolatile semiconductor memory device 1 is connected to the outside (e.g., a host device) via an input/output control circuit 10. The input/output control circuit 10 receives addresses and data from the outside via a data line and also receives a control signal from the outside via a control line. The input/output control circuit 10 performs interfacing with external circuits in accordance with a predetermined protocol.

An address register 11 latches an address sent from the input/output control circuit 10. This address contains a row address for selecting a row in a memory cell array 22. The address register 11 sends the row address out of the latched address to a row decoder 15. The row decoder 15 selects any one of the word lines on the basis of the row address.

A control circuit 12 controls each internal module in response to the control signal (e.g., a command) from the outside. Although not all of the signal lines to the modules from the control circuit 12 are shown to avoid complication of the drawing in FIG. 2, the control circuit 12 actually controls all the modules within the nonvolatile semiconductor memory device 1. The control circuit 12 is provided with a random access memory (RAM) as a work area and a read only memory (ROM) for storing a control program and others, and uses these memories to perform control operation.

A voltage generating circuit 13 generates various voltages necessary for the nonvolatile semiconductor memory device 1. Thus, the voltage generating circuit 13 includes, for example, a D/A converter for generating the various voltages. Voltages such as a write voltage Vp and a read voltage Vr generated by the voltage generating circuit 13 are applied to the respective word lines in accordance with decode information in the row decoder 15.

A sense amplifier circuit 21 reads data from a bit line selected by a column selection signal sent from the control circuit 12. Thus, the sense amplifier circuit 21 generates several fixed voltages in accordance with operations requested by each register in data writing and write check steps, and applies the fixed voltages to bit lines. For example, in reading data, the sense amplifier circuit 21 precharges bit lines with a predetermined voltage. Here, a read voltage corresponding to information is applied to the word line connected to a read target memory cell, while a read pulse voltage that turns on a cell independently of stored information is applied to word lines connected to memory cells other than the read target memory cell. Then, the sense amplifier circuit 21 reads the information recorded in the read target memory cell depending on whether the bit line is discharged with the potential.

The memory cell array 22 is configured by a NAND flash memory. Each of the memory cells included in the NAND flash memory is capable of recording two bits information. Thus, although an example of a system in which each memory cell records two bits information is described in the present embodiment, the present invention is not limited to this. The present invention is also applicable to a system in which each memory cell records information of three or more bits.

The memory cell array 22 includes 4096 bits lines BL arranged to extend in a column direction and 64 word lines WL arranged to extend in a row direction, wherein one memory cell disposed at each intersection serves as a unit, and, for example, 4096 such units are arranged in the column direction. Each control unit of the sense amplifier circuit 21 is connected to each bit line, and each unit included in the row decoder 15 is connected to each word line. 4096 memory cells are connected to one word line and each record two bits information, so that one word line has a recording capacity of 8192 bits. The unit of information recorded for one word line is referred to as a page, and data is written or read in page units. The unit of information recorded for 64 word lines is referred to as a block, and data is erased in block units.

Furthermore, in the present embodiment, in order to constrain interference between the bit lines, writing to a memory cell MC connected to one word line WL is performed in two separate steps for even bit lines BL and odd bit lines BL. That is to say, among the 4096 memory cells MC connected to one word line WL, write processing in a first step is performed for 2048 memory cells connected to the even bit lines BL, and write processing in a second step is performed for 2048 memory cells connected to the odd bit lines BL.

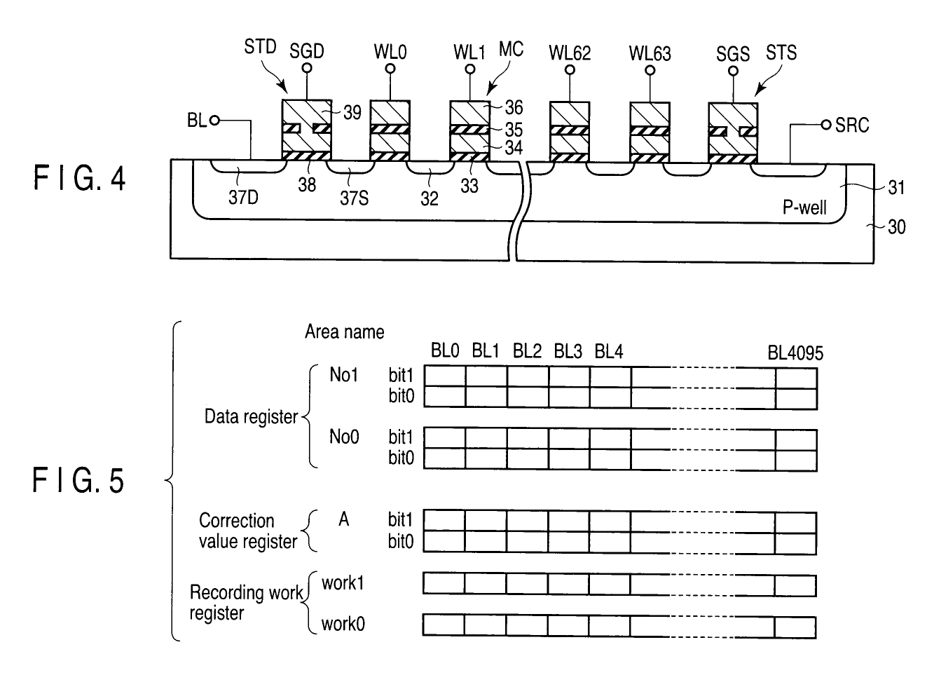

FIG. 3 is a diagram showing one example of the memory cell array 22 shown in FIG. 2. As shown in FIG. 3, the memory cell array 22 includes a plurality of blocks, for example, 4096 blocks BLK0 to BLK4095. Each block BLK has a plurality of NAND strings, for example, 4096 NAND strings. A selective transistor STD included in each of the plurality of NAND strings has its drain connected to the bit line BL and its gate connected to a common select gate line SGD. Moreover, A selective transistor STS included in each of the plurality of NAND strings has its source connected to a common source line SRC and its gate connected to a common select gate line SGS.

In each NAND string, a plurality of memory cells MC, for example, 64 memory cells MC are arranged between the source of the selective transistor STD and the drain of the selective transistor STS so that their current paths are connected in series. That is, the plurality of memory cells MC are connected in series in the column direction so that adjacent memory cells share a diffusion region (source region or drain region).

Furthermore, control gate electrodes are respectively connected to word lines WL0 to WL63 in this order starting from the memory cell MC located closest to the drain side. Thus, the drain of the memory cell MC connected to the word line WL0 is connected to the source of the selective transistor STD, and the source of the memory cell MC connected to the word line WL6 is connected to the drain of the selective transistor STS.

Moreover, a common bit line BL connects the drains of the selective transistors STD between blocks. That is, the NAND strings on the same column in a plurality of blocks are connected to the same bit line BL.

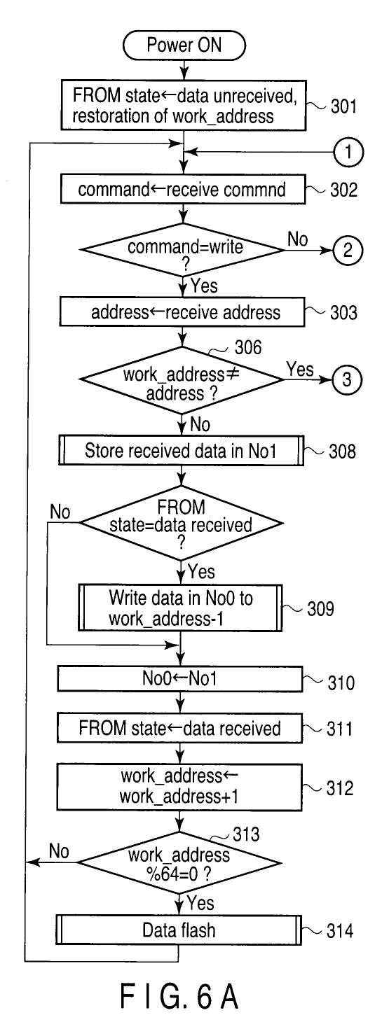

FIG. 4 is a sectional view showing the configuration of one NAND string. In a semiconductor substrate 30, a P-well 31 is formed. Each memory cell MC is configured by a metal oxide semiconductor field effect transistor (MOSFET) having a stack gate structure formed on the P-well 31. The stack gate structure has a tunnel insulating film 33, a charge storage layer (floating gate electrode) 34, an intergate insulating film 35 and a control gate electrode 36 that are stacked on the P-well 31 in this order. A diffusion region (source region or drain region) 32 is provided in the P-well 31 between adjacent stack gate structures.

The threshold voltage of the memory cell MC changes depending on the number of electrons in the floating gate electrode 34, and the memory cell MC records data depending on the variation of the threshold voltage. In addition, the memory cell MC may be a floating gate type memory cell in which the charge storage layer is a floating gate electrode made of a conductor such as polycrystalline silicon, or a metal-oxide-nitride-oxide-semiconductor (MONOS) type memory cell in which the charge storage layer is an insulator such as silicon nitride. In the case of the MONOS type memory cell, the intergate insulating film 35 is referred to as a block insulating film.

The selective transistor STD includes a source region 37S and a drain region 37D separately provided in the P-well 31, a gate insulating film 38 provided on a channel region between the source region 37S and the drain region 37D, and a gate electrode 39 provided on the gate insulating film 38. The selective transistor STS has the same configuration.

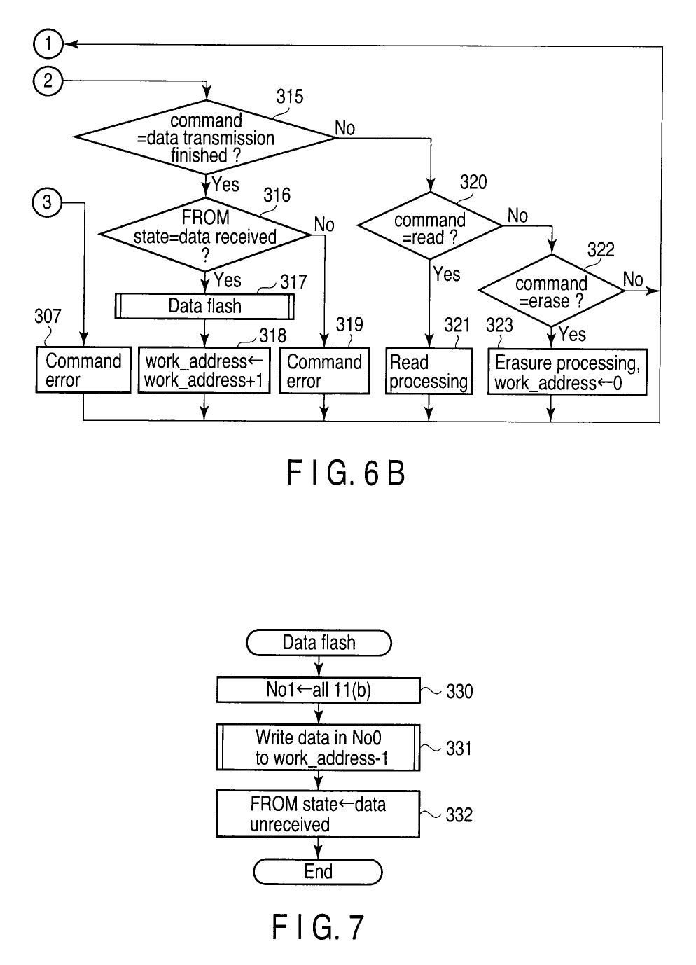

Returning to FIG. 2, a data register 0 (16), a data register 1 (17), a correction value register (18), a recording work register 0 (19) and a recording work register 1 (20) are registers which retain one bit or two bits information for each bit line in the memory cell array 22. Each of the data registers 0 and 1 has a capacity of two bits per bit line. The correction value register also has a capacity of two bits per bit line. Each of the recording work registers 0 and 1 has a capacity of one bit per bit line. FIG. 5 is a schematic diagram showing the configuration of the work registers.

In FIG. 5, one square represents a one bit memory. The data register 0 and the data register 1 are abbreviated as No0 and No1, respectively. The correction value register is abbreviated as A. The recording work register 0 and the recording work register 1 are abbreviated as work0 and work1, respectively. Moreover, for example, a correction value corresponding to the memory cell of the bit line BL0 is indicated as A[0] using an array notation in the C programming language. A[0] is a two bits value. Moreover, four-bit data per memory cell combining No0 and A is indicated as No0A. Two bits of No0 in No0A are high digits, and two bits of A are low digits.

[2. Operation of Nonvolatile Semiconductor Memory Device 1]

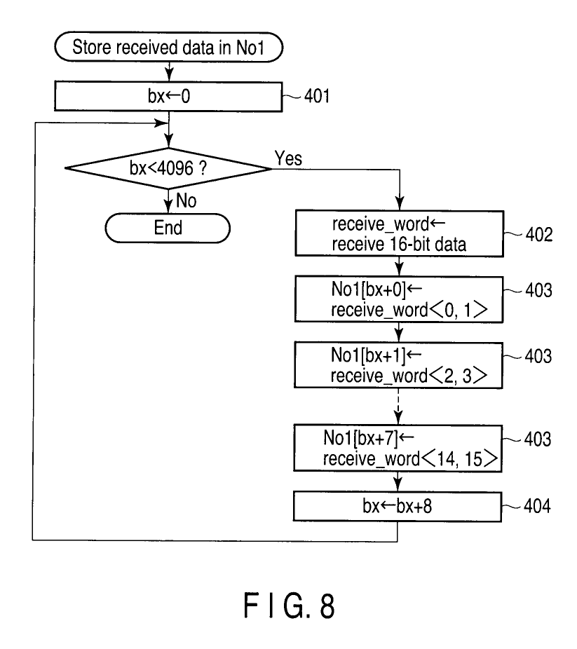

Now, the overall operation of the nonvolatile semiconductor memory device 1 is described. FIGS. 6A and 6B are flowcharts showing the overall operation of the nonvolatile semiconductor memory device 1.

When the nonvolatile semiconductor memory device 1 is powered on, the control circuit 12 sets an internal variable_FROM state to a data nonreceiving state, and at the same time, restores an internal variable work_address from the data that is backed up (step 301). The internal variable work_address is data which is backed up, when needed, in a nonvolatile memory (not shown) such as a NOR type flash memory. The value of the internal variable work_address is zero at the factory. The “internal variable” is data retained by the control circuit 12, and is used for the processing in the control circuit 12.

Then, the nonvolatile semiconductor memory device 1 receives a command from the host device, and sets the command to an internal variable command (step 302). The command includes a write command, a read command, erasure command and a data transmission end command.

When the internal variable command is the write command, the nonvolatile semiconductor memory device 1 then receives an address from the host device (step 303). The received address is stored in the address register 11, and is set to an internal variable address. This address is a numerical value that specifies a word line, and a value equal to or more than 0 and equal to or less than “64×4096−1” is a valid value.

Then, the control circuit 12 compares the received address (i.e., the internal variable address) with the internal variable work_address (step 306). If these variables are different, the control circuit 12 regards this as a command error (step 307), and returns to step 302 to wait for the next command. On the other hand, when the internal variable address is equal to the internal variable work_address, the control circuit 12 then receives data from the host device, and stores the received data in the data register No1 (step 308). The processing for storing the received data in the data register No1 in step 308 will be described later.

Furthermore, when the internal variable_FROM state is in a data received state, the control circuit 12 writes data in the data register No0 into a word line indicated by “work_address-1” (step 309). The write processing in step 309 will be described later.

Then, the control circuit 12 copies data in the data register No1 to the data register No0 (step 310). Subsequently, the control circuit 12 changes the state of the internal variable_FROM state to a data received state (step 311), and increases the internal variable work_address by one (step 312).

The processing is normally ended here to return to the wait for the next command. However, when the last page of the block is reached, data is also written to the word line corresponding to the last page. That is, when the internal variable work_address has reached a multiple of 64 (step 313), the control circuit 12 performs data flash processing (step 314). “%” in step 313 of FIG. 6A is an operator for dividing the numerical value on the left side by the numerical value on the right side to find a remainder.

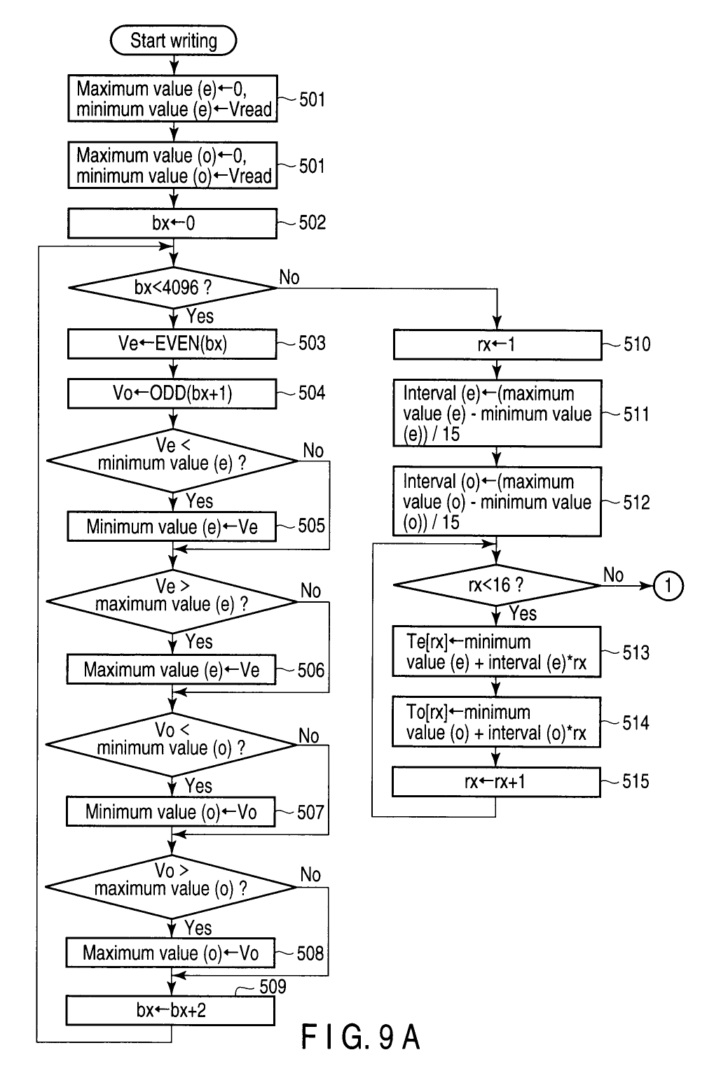

FIG. 7 is a flowchart showing the data flash processing performed by the control circuit 12. The control circuit 12 sets all the register values of the data register No1 to “11(b)” (step 330). (b) is a symbol that means a binary number. Then, the control circuit 12 writes the data in the data register No0 to a word line indicated by “work_address-1” (step 331). Then, the control circuit 12 sets an internal variable_FROM state to a data nonreceiving state (step 332). After the end of the data flash processing, the control circuit 12 returns to waiting for the next command.

Furthermore, when the internal variable command is the data transmission end command (step 315), the control circuit 12 performs the data flash processing described with FIG. 7 if the internal variable_FROM state is in a data received state (step 316).

Then, the control circuit 12 increases the internal variable work_address by one (step 318). That is, once successive writing has been finished, the address of a write command that can be further received indicates the word line one line apart from the last recorded word line. If no write command has been received in step 316 since the power application or since the end of the previous data transmission, that is, if the state of the internal variable_FROM state is the data unreceived state, the control circuit 12 handles this as a command error (step 319), and returns to waiting for the next command.

When receiving other commands, for example, when the internal variable command is the read command (step 320), the control circuit 12 appropriately performs reading processing for this command (step 321) and returns to waiting for the next command. For this reading processing, a technique that has heretofore been in wide use can be used. When the internal variable command is the erasure command (step 322), well-known erasure operation is performed, and the internal variable work_address is returned to zero (step 323).

[2-1. Processing for storing received data in data register No1]

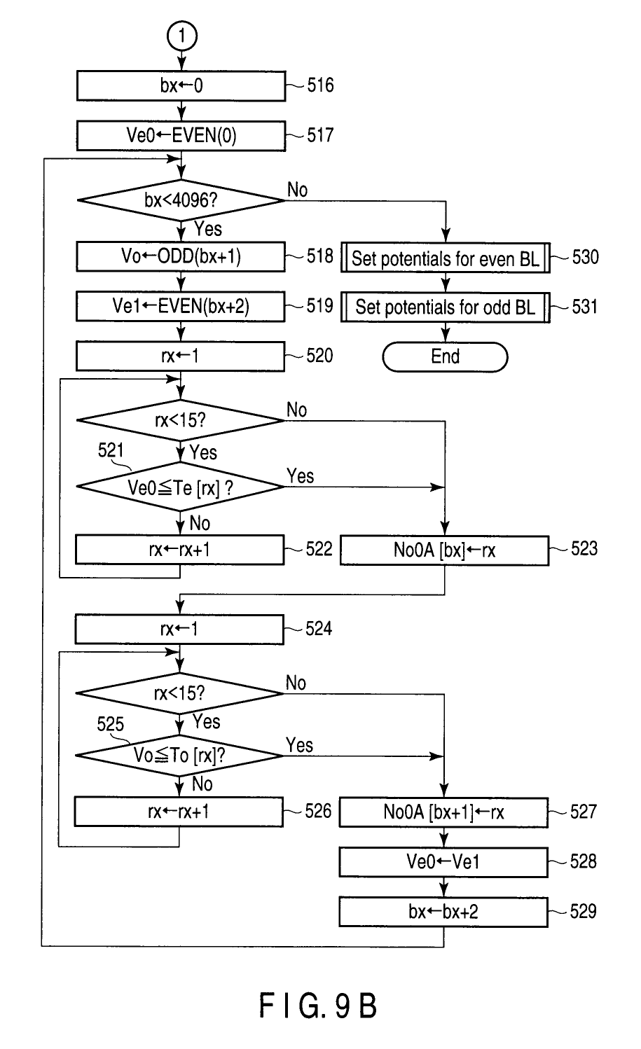

Now, details of processing for storing the received data in step 308 of FIG. 6A in the data register No1 are described. FIG. 8 is a flowchart showing processing in step 308 performed by the control circuit 12.

At the start of operation, the control circuit 12 sets (initializes) a counter variable bx to zero (step 401). “bx” represents the number of a bit line. In the reception of data following the commands and the addresses, one data reception is performed using 16 data lines, that is, 16 bits data is received (step 402). The received data is set to an internal variable receive word.

Then, the control circuit 12 separates the received 16 bits data by two bits to create eight values, and stores these values in eight successive positions starting from a position indicated by the counter variable bx in the data register No1 (step 403). For example, two initial bits of the received 16 bits data, that is, two bits data set in an internal variable receive_word <0, 1>are stored in the data register No1 [bx+0]. Step 403 in FIG. 8 is actually composed of eight storage processes, but intermediate processes are not shown. In addition, the processing in step 403 can also be achieved by transferring a value to eight elements of the data register No1 that continue by two bits from a 16 bits internal variable in some circuits.

Then, the control circuit 12 increases the counter variable bx by 8 (step 404). Further, the control circuit 12 performs this processing until the counter variable bx reaches 4096, that is, the control circuit 12 performs this processing 512 times in succession.

[2-2. Processing for Writing to Word Line]

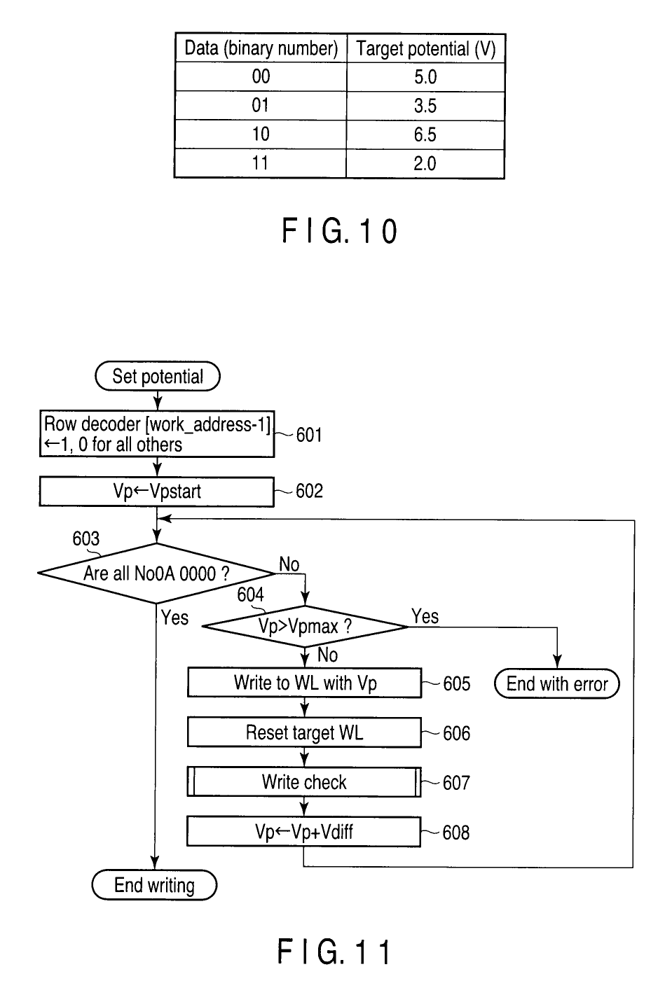

Now, details of processing for writing the data in the data register No0 to a word line indicated by “work_address-1” in step 309 of FIG. 6A are described. FIG. 9A and FIG. 9B are flowcharts showing the processing performed by the control circuit 12 in step 309.

The processing for writing the data in the data register No0 to the word line indicated by “work_address-1” is separated into the decision of a set potential allowing for a correction value and setting of a potential for the word line. Of these two operations, the decision of a set potential allowing for a correction value is mainly taken up in FIG. 9A and FIG. 9B.

First of all, a maximum value and a minimum value of a set potential are found for each memory cell. These values are independently found for even memory cells and odd memory cells, such that the accuracy of potential setting can be increased. From now on, throughout the embodiments, the numerical values for potentials such as the set potential, the target potential and the cell potential are, unless otherwise stated, relative potentials originating in a potential in an erased state, and are indicated by volts (V).

First, the control circuit 12 sets an internal variable_maximum value (e), a minimum value (e), a maximum value (o), a minimum value (o) at 0, Vread, 0, Vread, respectively (step 501). These values are temporary values to find the maximum value and the minimum value of the set potential of each of the even and odd memory cells. The maximum value (e) and the minimum value (e) represent the maximum value and the minimum value of the even memory cell, respectively. The maximum value (o) and the minimum value (o) represent the maximum value and the minimum value of the odd memory cell, respectively. The read pass voltage Vread is a potential of the control gate electrode that can bring any normal memory cell into a conducting state, that is, a potential higher than any target potential for recording into the memory cell, and is typically about 8 V.

Then, the control circuit 12 initializes the counter variable bx to zero (step 502). Further, the control circuit 12 calculates and assigns EVEN(bx) and ODD(bx+1) to internal variables Ve and Vc, respectively (steps 503, 504). Here, a calculating expression EVEN is:

$$EVEN ( x ) = Exp [ No 0 [ x ] ] - Yb * ( Exp [ No 0 [ x 1 ] ] + Exp [ No0 [ x + 1 ] ] ) - Yw * Exp [ No 1 [ x ] ] - Yc * ( Exp [ No 1 [ x - 1 ] ] + Exp [ No 1 [ x + 1 ] ] )$$

wherein a bit line of interest is taken as an argument x, and “*” is a multiplication sign.

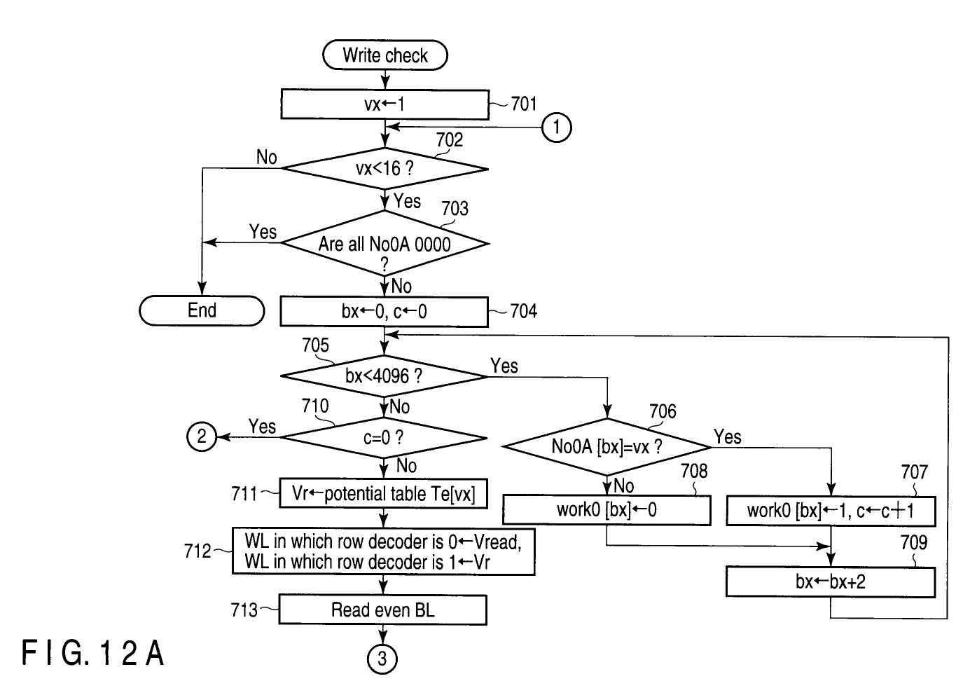

However, Exp[data] is a value in which a potential variation margin (typically, about 0.5 V) is added to a judgment threshold value between data to be recorded (binary number, two bits) and data one potential lower. This value signifies a value (target potential) equivalent to the lower limit of a set potential range desirable for the data to be recorded. This target potential is shown in FIG. 10.

As has already been described, No0[x], No1[x], etc. refer to xth values in array type data registers No0, No1. Depending on the value of x, calculations of x, x−1 and x+1 may exceed the array range of the data registers No0, No1, but these calculations are treated as if “11(b)” were written. Moreover, Yb, Yw, Yc are constants having the meaning that has been described at the beginning of the embodiment. Certain potentials are actually provided to several memory cells during the manufacture of the nonvolatile semiconductor memory device 1, and how the potentials of adjacent cells have been increased by a coupling effect is measured, and then Yb, Yw, Yc are calculated and averaged. Yb, Yw, Yc are recorded in the ROM within the control circuit 12. Typically, Yb, Yw are about 0.1, and Yc is about 0.01.

Similarly, a calculating expression ODD having x an argument is:

$$ODD ( x ) = Exp [ No 0 [ x ] ] - Yw * Exp [ No 1 [ x ] ] - Yc * ( Exp [ No 1 [ x - 1 ] ] + Exp [ No 1 [ x + 1 ] ] ) .$$

Then, the control circuit 12 decides a maximum value and a minimum value. The control circuit 12 sets Ve as a minimum value (e) when Ve<minimum value (e) (step 505). The control circuit 12 sets Ve as a maximum value (e) when Ve>maximum value (e) (step 506). The control circuit 12 sets Vo as a minimum value (o) when Vo<minimum value (o) (step 507). The control circuit 12 sets Vo as a maximum value (o) when Vo>maximum value (o) (step 508).

Then, the control circuit 12 increases the counter variable bx by 2 (step 509). Further, the control circuit 12 returns to the head of the loop, and performs similar processing until the counter variable bx reaches 4096.

Then, the control circuit 12 creates potential tables (potential table Te, potential table To) for even/odd bit lines. Each of the even and odd potential tables has 15 elements, and the first to fifteenth elements have effective values. The values in the potential tables indicate set potentials applied to the word lines during writing. An rx-th value in the potential table Te can be obtained by the following calculating expression (step 513):

$$Te [ rx ] = minimum value ( e ) + ( ( maximum value ( e ) - minimum value ( e ) ) / 15 ) * rx .$$

In other words, the control circuit 12 calculates “(maximum value (e)−minimum value (e))/15”, and sets an obtained value as an internal variable_interval (e) (step 511). Further, the control circuit 12 repeats the following calculating expression until rx reaches 16 to create the potential table Te:

Te[rx]=minimum value (e)+interval (e)*rx.

The potential table Te [15] is equal to the maximum value (e).

Similarly, an rx-th value in the potential table To can be obtained by the following calculating expression (step 514):

$$To [ rx ] = minimum value ( o ) + ( ( maximum value ( o ) - minimum value ( o ) ) / 15 ) * rx .$$

In other words, the control circuit 12 calculates “(maximum value (o)−minimum value (o))/15”, and sets an obtained value as an internal variable_interval (o) (step 512). Further, the control circuit 12 repeats the following calculating expression until rx reaches 16 to create the potential table To:

To[rx]=minimum value (o)+interval (o)*rx.

The potential table To [15] is equal to the maximum value (o).

Then, the control circuit 12 finds a set potential No0A to be set in each memory cell. First, the control circuit 12 initializes the counter variable bx to zero (step 516). Further, the control circuit 12 finds and sets a set potential for the bit line BL0 as an internal variable Ve0 (step 517). EVEN(0) which has already been described is used as a calculating expression.

Then, the control circuit 12 calculates a set potential for the bit line BL(bx+1) and assigns the set potential to an internal variable Vo (step 518). ODD(bx+1) which has already been described is used as a calculating expression. Moreover, the control circuit 12 calculates a set potential for the bit line BL(bx+2) and assigns the set potential to an internal variable Ve1 (step 519). EVEN(bx+2) which has already been described is used as a calculating expression.

Then, the control circuit 12 searches for a position on the potential table Te to which Ve0 belongs. First, the control circuit 12 initializes the internal variable rx to 1 (step 520). Further, the control circuit 12 searches for rx that first satisfies Ve0≦potential table Te[rx]. The control circuit 12 checks whether Ve0≦potential table Te[rx] is satisfied only while rx is not up to 15, and the control circuit 12 escapes out of the loop when Ve0≦potential table Te[rx] is satisfied (step 521). When Ve0≦potential table Te[rx] is not satisfied, the control circuit 12 increases rx by 1 and continues with the loop (step 522). When rx has reached 15, the control circuit 12 always ends the loop. Further, the control circuit 12 sets rx at that moment as No0A[bx] (step 523). No0A[bx] is never set to zero, and is always 1 or more and 15 or less. Although a sequential search scheme is used to decide rx in the present embodiment, other well-known schemes for accelerating the search, such as a binary search can also be used.

Similarly, the control circuit 12 searches for a position on the potential table To to which Vo belongs. The procedure of the search is similar to the procedure in steps 520 to 523, so that Ve0 is read as Vo, the potential table Te is read as the potential table To, and No0A[bx] is read as No0A[bx+1].

Then, preparations are made to evaluate the next set of bit lines. First, the control circuit 12 sets the value of Ve1 to the internal variable Ve0 (step 528). Further, the control circuit 12 increases the counter variable bx by 2 (step 529), and returns to the beginning of the loop. The control circuit 12 escapes out of this loop when bx is 4096.

Ve0 and Ve1 are separated for the following reason: If a new value is set for No0A[bx+1] in step 527, this can be referred to in the next loop by No0[bx−1], A[bx−1]. If EVEN(bx) is calculated in step 519, No0[bx−1] is referred to, so that a (corrected) value different from the value input from the host device is referred to.

The even and odd potential tables and the set potential for each bit line are decided by the processing described above. Further, the control circuit 12 sets potentials for even bit lines (step 530). Then, the control circuit 12 sets potentials for odd bit lines (step 531).

[2-3. Processing for Setting Potentials for Bit Lines]

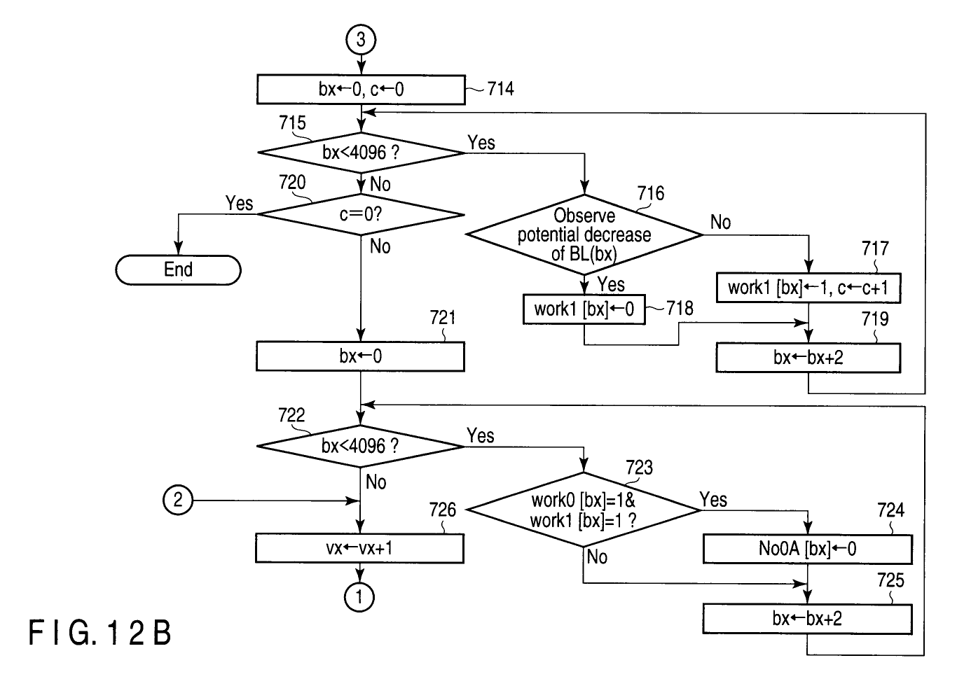

Now, details of processing for setting potentials for bit lines in step 530 of FIG. 9B are described. FIG. 11 is a flowchart showing the processing performed by the control circuit 12 in step 530.

First, the control circuit 12 writes 1 at a position (unit) of the row decoder corresponding to a value in which 1 is subtracted from the internal variable work_address, and writes zero at other positions (step 601). The internal variable work_address indicates the word line to which page data has been written last by the host device, but the target for potential setting in FIG. 11 is the page data that has been received from the host device one time before. So, a word line indicated by “work_address-1” is selected in the step 601.

Furthermore, the control circuit 12 sets Vpstart to an internal variable Vp (step 602). Vpstart is an initial pulse height (unit: V) output as a write pulse sequence, and is typically about 18 V. Further, the control circuit 12 checks whether there remains any bit to be set (step 603). The bit to be set means a bit in which No0A[bx] (however, bx is an even number) is not zero. When there is even one bit to be set, the control circuit 12 checks whether the write voltage Vp has reached Vpmax (step 604). Vpmax is the greatest pulse height (unit: V) that can be output as a write pulse sequence, and is typically about 27.5 V. When the write voltage Vp is beyond Vpmax, recording is a failure.

Then, the control circuit 12 writes to the word line with the write voltage Vp (step 605). Specifically, this operation is as follows: The potentials of all the bit lines having odd bx and the potentials of the bit lines in which No0A[bx] is zero, that is, the bit lines which are not targeted for writing among the bit lines having even bx are once increased to a power supply potential Vdd (about 405 V against ground) and then brought into a floating state. On the other hand, the potentials of the bit lines which have even bx and in which No0A[bx] is not zero, that is, the potentials of the bit lines targeted for writing are grounded. Further, a write pass voltage Vpass (about 10 V against ground) is applied from the voltage generating circuit 13 to all the word lines in which the value of the row decoder is zero, and the write voltage Vp is applied from the voltage generating circuit 13 to the word line in which the value of the row decoder is 1. Thus, the control circuit 12 waits for a certain period of time to pass. This operation is the same as the operation based on a recording scheme which is performed in a conventional NAND flash memory except for the way that a bit line is selected.

Then, the control circuit 12 resets the target word lines (step 606). This means waiting for the potentials of the control gates in all the memory cells to be at 0 V against ground as a result of decreasing the voltages of all the word lines to 0 V against ground at the end of step 605. This is accomplished by waiting for a certain period of time. Further, the control circuit 12 conducts a write check (step 607). This write check processing will be described later.

Then, the control circuit 12 increases the write voltage Vp by a voltage Vdiff (step 608). The voltage Vdiff corresponds to one of voltages at equal intervals between Vpstart and Vpmax, and is typically about 0.1 V. Further, the control circuit 12 returns to step 603, and repeats the loop while sequentially stepping up the write voltage Vp by Vdiff until writing to all the memory cells to which data is to be written finishes.

[2-4. Write Check Processing]

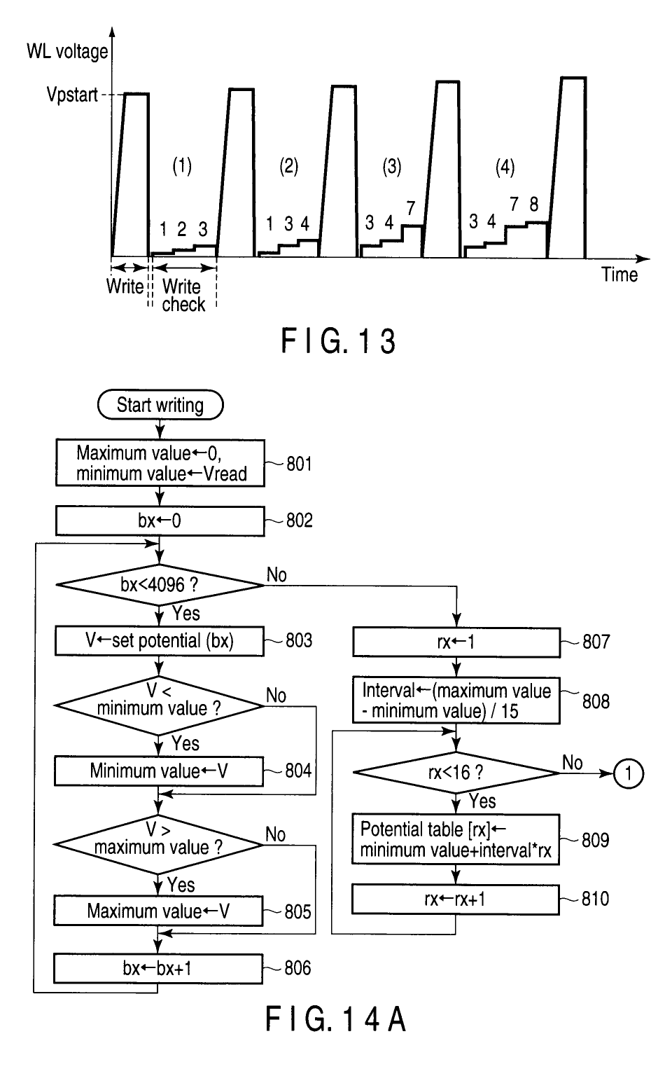

Now, details of write check processing in step 607 of FIG. 11 are described. FIG. 12A and FIG. 12B are flowcharts showing the processing performed by the control circuit 12 in step 607.

In the write check processing, the control circuit 12 first initializes a counter variable vx to 1 (step 701). The counter variable vx is a counter which sequentially switches a check potential for examining the potential that has already been set. Further, the control circuit 12 checks whether vx is 16 (step 702). If vx has reached 16, the write check is finished.

If vx is below 16, the control circuit 12 then checks whether No0A[bx] is zero for all even bx (step 703). If No0A[bx] is zero for all even bx, this means that there are no more memory cells that need their potentials set, so the write check is finished.

If there is one or more bx in which No0A[bx] is not zero, the control circuit 12 then checks whether there is No0A[bx] in which currently selected vx is the set potential. First, the control circuit 12 initializes the counter variables bx and c to 1 (step 704).

If bx has not reached 4096 (step 705), the control circuit 12 checks whether No0A[bx] is equal to vx (step 706). If No0A[bx] is equal to vx, the control circuit 12 sets 1 to a work register work0[bx], and increases the counter variable c by 1 (step 707). If No0A[bx] is not equal to vx, the control circuit 12 sets zero to the work register work0[bx] (step 708). The control circuit 12 increases the counter variable bx by 2 in each case (step 709), and returns to step 705 to check whether bx has reached 4096.

When bx has reached 4096, the control circuit 12 then checks whether c is equal to 0 (step 710). c=0 means that there is no memory cell that is expected to be a set potential corresponding to vx. Therefore, the write check for the set potential is unnecessary, so that the control circuit 12 proceeds to step 726 and calculates the next vx.

When c is not zero, the control circuit 12 sets, to an internal variable Vr, a value obtained by searching a potential table Te[vx] (step 711). This Vr serves to judge whether the potential of a memory cell has reached the read voltage Vr. Further, the read pass voltage Vread is applied to the word line in which the value of the row decoder is zero, while the read voltage Vr is applied to the word line in which the value of the row decoder is 1 (step 712). The value of the read pass voltage Vread is the same as that described in step 501.

Then, the control circuit 12 reads the even bit lines (step 713). Reading the bit lines means the operation as follows: The source side of the memory cell connected to the even bit line is first shut off, and then the drain side is rised to a voltage for read judgment, for example, 0.5 V against ground. Further, the drain side is shut off, and the source side is grounded, so that the control circuit 12 waits for a certain period of time to check whether the charge stored on the drain side is released. If the memory cell is in a conducting state, the charge flows from the source side, and the voltage on the drain side decreases. However, most of this voltage remains even after the certain period of time if this memory cell is in a conducting state. The voltage of the bit line at this moment is read by the sense amplifier circuit 21.

A reading procedure is as follows: The control circuit 12 first initializes the counter variables bx and c to zero (step 714), examines whether bx is less than 4096 (step 715), and checks whether the potential of a bx-th bit line has decreased if bx is less than 4096 (step 716). If the potential of the bx-th bit line has decreased, the control circuit 12 sets zero to the work register work1[bx] (step 718). An erased memory cell is in a conducting state when a given read voltage Vr which is zero or more against a erasure level is applied to the memory cell, while a memory cell is not conductive without any application of a higher read voltage Vr as more data is written to the memory cell, that is, more electrons are injected into the floating gate electrode. Therefore, that the memory cell is in the conducting state with the set potential being applied means that a necessary write amount is not reached. On the contrary, if no potential is decreased, writing up to the set potential corresponding to the potential table Te[vx] is finished. In this case, the control circuit 12 writes 1 to the work register work1[bx], and increases c by 1 (step 717). In each case, the control circuit 12 increases bx by 2 (step 719), and returns to step 715 to check whether all the even bit lines have been examined.

If all the even bit lines have been examined, the control circuit 12 checks whether c is zero (step 720). That c is zero means that there is no memory cell which has reached the set potential corresponding to the potential table Te[vx] at the moment. Therefore, there is no use in setting a potential higher than the current read voltage Vr for examination. Thus, the current write check is finished.

If c is not zero, the control circuit 12 then checks whether there is any memory cell which has reached the set potential. The control circuit 12 first initializes the counter variable bx to zero (step 721). Further, the control circuit 12 checks whether bx is below 4096 (step 722). When bx is less than 4096, the control circuit 12 then checks whether both the work registers work0[bx], work1[bx] are 1 (step 723). That both the work registers work0[bx] and work1[bx] are 1 means that data is expected to be written to the memory cell up to the current read voltage Vr and that this writing has been achieved at this moment. In that case, the control circuit 12 sets zero for No0A[bx] (step 724). This bit line is not targeted for writing in the next period or for a write check. Further, the control circuit 12 increases bx by 2 in each case (step 725), and returns to step 722 to check whether bx has reached 4096.

When bx has reached 4096, the write check with this read voltage Vr finishes. The control circuit 12 increases vx by 1 for the next loop (step 726), and returns to step 702 to check whether vx has reached 16.

In addition, the processing from step 704 to step 709, the processing from step 714 to step 719 and the processing from step 721 to step 725 can be performed at the same time by a plurality of circuits in some embodiments.

The procedure for setting potentials for the odd bit lines in step 531 in FIG. 9B is substantially similar to the procedure for setting potentials for the even bit lines. The flowcharts referred to are similar to the flowcharts in FIG. 11 and FIG. 12. However, the potential table To is used instead of the potential table Te. Even is read as odd, and odd is read as even. The initial value of the loop control by the counter variable bx is changed to 1.

[3. Specific Example of Potential Setting for Bit Lines and Write Check]

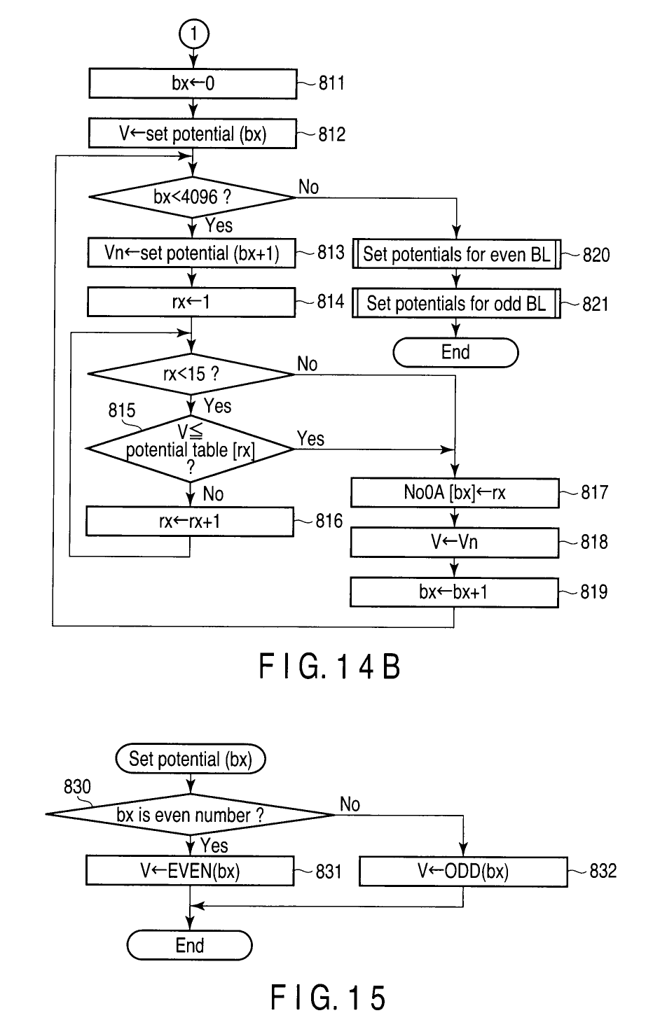

Now, a specific example of the potential setting for even bit lines and the operation of the write check described in FIG. 11 and FIG. 12 is described. FIG. 13 is a graph showing the potential setting for even bit lines and the change of the potential applied to a write target word line in the write check. This example shows the middle part of write operation, and the potential setting operation continues before and after this part. The vertical axis in FIG. 13 indicates the potential (originating in an erasure level) applied to the word line, and the horizontal axis indicates time (originating in the start time of recording). At the start of writing, No0A includes, for example, elements that take 1, 2, 3, 4, 7, 8 and does not include 0, 5, 6.

The write check follows writing the first Vp in FIG. 13. In the write check, the counter variable vx is sequentially increased from 1 to a larger number. After recognition in step 710 that the memory cell of No0A=1 is present, a write check is decided to be conducted in this period, and a set potential corresponding to a potential table Te[1] in step 712 is applied to a word line in which the value of the row decoder is 1, so that the memory cells having cell potentials equal to or more than the set potential are checked ((1)-1 in FIG. 13). As a result, the potentials of some memory cells have reached the potential table Te[1], but some of the memory cells of No0A=1 still branch to NO in step 723, that is, do not reach the set potential of the potential table Te[1].

Then, vx is set to 2 in step 726, and the set potential of a potential table Te[2] for the presence of the memory cell of No0A=2 is applied to the word line, so that the memory cells having cell potentials equal to or more than the set potential are checked ((1)-2 in FIG. 13). As a result, all the memory cells of No0A=2 branch to YES in step 723, that is, reach the set potential of the potential table Te[2]. Here, zero is written to No0A[bx] in step 724, so that all terms of No0A=2 at this moment are rewritten to zero.

Furthermore, vx is set to 3 in step 726, and the set potential of a potential table Te[3] for the presence of the memory cell of No0A=3 is applied to the word line, so that the memory cells having cell potentials equal to or more than the set potential are checked ((1)-3 in FIG. 13). As a result, all the memory cells including the memory cells targeted for higher potentials are detected to have not reached this potential. Therefore, the step of applying a higher word line voltage is stopped to end the write check in step 720, and the second Vp is written.

In the write check after writing the second Vp, memory cells in which No0A=1 are present, thus the set potential of the potential table Te[1] is applied to the word line to check the potential of each memory cell. As a result, it is found that all the memory cells of No0A=1 have reached the set potential of the potential table Te[1], and No0A at all the positions is set to zero (step 724). Further, vx=2 is set to check such memory cells that No0A=vx. However, as zero has been written to all the terms of No0A=2 in the first writing and the following writing, c=0 in step 710, and the next potential follows without any write check for vx=2.

Furthermore, vx=3 is set to check the memory cells whose potentials have reached the set potential of the potential table Te[3] ((2)-3 in FIG. 13). After recognition that some of the memory cells have reached the set potential, No0A is set to zero. The rest of the memory cells have not been able to reach the set potential, for which No0A is kept at 3. Further, vx=4 is checked ((2)-4 in FIG. 13). After recognition that there are no memory cells which have reached the set potential of a potential table Te[4], the second write check is finished in accordance with the judgment in step 720, and the third Vp is written.

The write check after writing the third Vp is performed as in the first Vp and the second Vp. However, since there is no such element that No0A=5 or 6 from the beginning, vx corresponding to these values are skipped in step 710.

Thus, the write check can be carried out without wasting time owing to the function of skipping the write check in the case where there is no No0A corresponding to vx targeted for the current check step 710, or owing to the function of performing no further write checks in the case where the potentials of all the memory cells are less than the set potential of the potential table Te[vx].

[4. Advantage of the Invention]

Data writing in accordance with conventional schemes requires four steps for even bits lines and odd bits lines: (1) lower bit writing+lower bit write check, (2) upper bit (01b) writing+write check, (3) upper bit (00b) writing+write check, (4) upper bit (10b) writing+write check.

On the contrary, the write scheme in the present embodiment is capable of finishing writing in only one step of “all bit writing+write check”. As a result, writing can be finished with a shorter writing time.

Furthermore, when the write check processing of the present embodiment is performed, the write check can be performed exclusively for the really necessary read voltage Vr as shown in FIG. 13, such that the time necessary for the write check can be minimized.

Furthermore, as shown in FIG. 6, once the data transmission end command is received, the data flash processing is performed, and the acceptance of the next write command can be started from the word line one line apart from the word line to which data has been written at the moment. Consequently, the degree of the influence on the potential of the memory cell of the last word line in which data has already been written by the potential of the memory cell of the word line in which data is newly started to be written can be reduced.

In addition, in writing the first set potential in one of two adjacent memory cells and writing the second set potential in the other memory cell, the potential variation in the first memory cell is about “0.5*V*Y” at the maximum at the point where writing of the upper bit is finished because a potential difference resulting from the writing of the lower bit is corrected when the upper bit is written in the case of the writing based on the conventional scheme. “V” is the potential difference between the potential in an erased state and the maximum one of the potentials of the memory cells to which corresponding data are allocated. “Y” is the rate of a coupling effect present between two adjacent memory cells. This relation is satisfied between two adjacent memory cells, and three cells adjacent to the first memory cell have about the same influence, so that a potential variation of about “1.5*V*Y” is made at the maximum.

On the contrary, in the writing method according to the present embodiment, the calculating expressions for EVEN and ODD described in steps 503, 504 include errors produced by omitting the terms of high orders equal to or more than the square of Y, so that a potential variation of about “7*V*Y²” is made at the maximum. Moreover, a rounding error is produced in the calculating expressions when the potential tables Te, To are created. However, the degree of this error is about “0.067*7” if the range of V is divided into fifteen equal parts. However, while the error produced by omitting the term is directed to drop the potential, the rounding error for creating the potential tables Te, To is directed to raise the potential, so that these errors generally offset each other. Thus, the error according the present scheme is about “max(0.067*V, 7*V*y²)” at the maximum. Provided that Y=0.1 and V=6.0, 0.067*V, 7*V*Y² is about 0.4 to 0.42 (V). This value is smaller than a fluctuation band 0.9 (V) in the conventional scheme. In other words, the present embodiment enables more accurate potential setting.

### Second Embodiment

In a second embodiment, when a sequential write is once finished in response to the data transmission end command, writing for the write command successively received is started from the word line two lines apart from the last recorded word line. Specifically, in step 318 in FIG. 6B, “work_address←work_address+1” is changed to “work_address←work-address+2”. The operation is the same as that in the first embodiment in other respects.

Owing to the change to such processing, the potential variation in the word line to which data has been newly written can have less influence on the last word line to which data has been previously written than in the first embedment when the successive recording is once stopped and then resumed. Specifically, when a coupling constant between word lines is Yw, the influence of Yw² that still remains in the first embodiment can be reduced to about Yw³ in the second embodiment.

It should be understood that an additional value to be added to an address when recording is newly resumed, that is, the number of word lines to leave space from the last recorded word line may be three or more.

### Third Embodiment

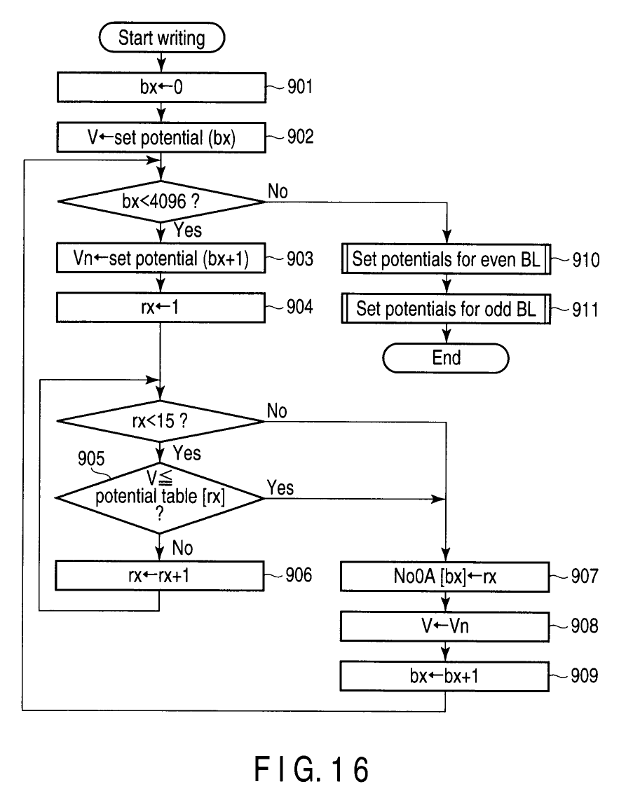

The third embodiment is different from the first embodiment in the configuration of the potential table which indicates the set potentials to be applied to the word line during writing. The two potential tables Te, To shown in FIG. 9A in the first embodiment are combined into one potential table. FIG. 14A and FIG. 14B are flowcharts showing processing for writing into a word line according to the third embodiment.

At the start of writing, the control circuit 12 sets zero to an internal variable_maximum value, and Vread to a minimum value (step 801). Here, the maximum value is a combination of the maximum value (e) and the maximum value (o) in FIG. 9A, and the minimum value is a combination of the minimum value (e) and the minimum value (o) in FIG. 9A.

Then, the control circuit 12 initializes the counter variable bx to zero (step 802), and decides the maximum value and the minimum value while bx<4096. That is, the control circuit 12 calculates a set potential for the bit line BL(bx) and assigns the set potential to an internal variable V (step 803). If V is less than the minimum value, the control circuit 12 assigns V to the minimum value (step 804). On the other hand, if V is beyond the maximum value, the control circuit 12 assigns V to the maximum value (step 805). Further, the control circuit 12 increases the counter variable bx by 1 (step 806). Further, the control circuit 12 returns to the head of the loop, and performs similar processing until the counter variable bx reaches 4096.

Then, the control circuit 12 creates a potential table. First, the control circuit 12 assigns 1 to rx (step 807), and calculates “(maximum value−minimum value)/15” to set an internal variable_interval (step 808). Further, the control circuit 12 repeats the following calculating expression until rx reaches 16 to create the potential table:

Potential table [rx]=minimum value+interval*rx.

Then, the control circuit 12 finds a set potential No0A[bx] to be set in each memory cell. First, the control circuit 12 initializes the counter variable bx to zero (step 811), and calculates a set potential for the bit line BL0 and assigns the set potential to the internal variable V (step 812).

Then, the control circuit 12 repeats the following processing until bx reaches 4096: The control circuit 12 calculates a set potential for the bit line BL(bx+1) and assigns the set potential to an internal variable Vn (step 813). While increasing rx from 1 to 15, the control circuit 12 searches for rx whereby the value of the potential table Te[rx] is equal to or more than V (step 815). If such rx is found, the control circuit 12 sets this rx to No0A[bx]. If not, the control circuit 12 sets 15 to No0A[bx] (step 817). Further, the control circuit 12 assigns Vn to the internal variable V, and increases bx by 1 (step 819).

After this processing, the control circuit 12 sets potentials for even bit lines (step 820) and sets potentials for odd bit lines (step 820), and then finishes the processing.

Although the sequential search scheme is used to decide rx in the present embodiment, other well-known schemes for accelerating the search, such as the binary search can also be used.

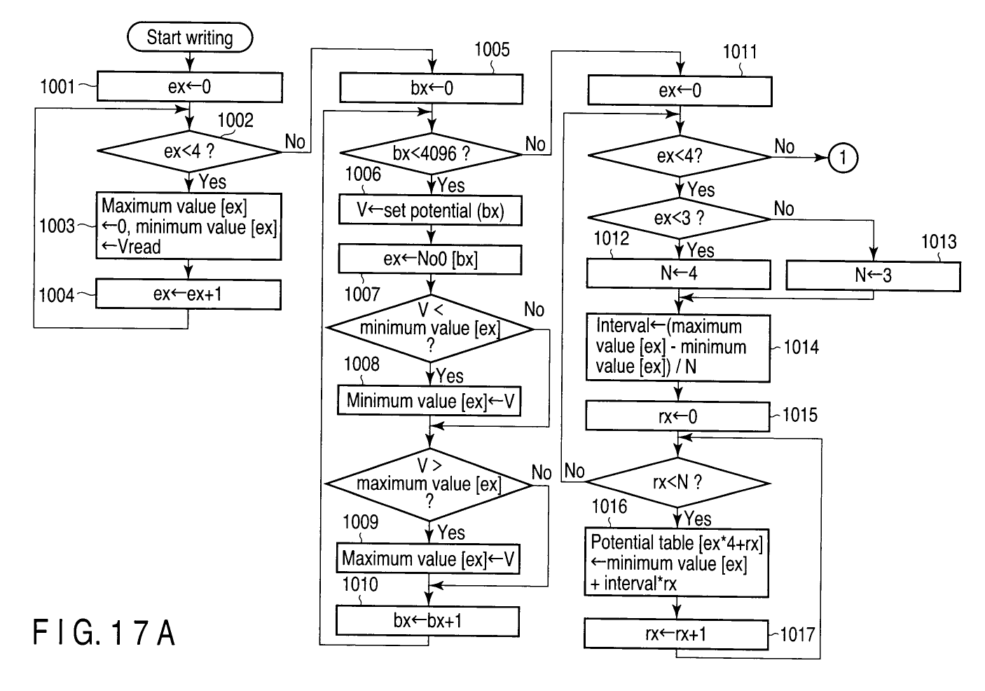

FIG. 15 is a flowchart explaining processing for calculating a set potential for the bit line BL(bx) in step 803. First, the control circuit 12 judges whether bx is an even number or odd number (step 830). If bx is an even number, the control circuit 12 calculates EVEN(bx) and assigns EVEN(bx) to the internal variable V (step 831). If bx is an odd number, the control circuit 12 calculates ODD(bx) and assigns ODD(bx) to the internal variable V (step 832). Here, the definitions of EVEN and ODD, and the processing method in the case where bx, bx−1 or bx+1 exceeds the array range of the data registers No0, No1 are exactly the same as those in the first embodiment.

Furthermore, while the potential tables Te and To are referred to in the first embodiment in the write check in the potential setting for even bit lines and the potential setting for odd bit lines, one combined potential table is referred to both in the potential settings for even bit lines and odd bit lines in the third embodiment.

As described above in detail, the distributions of the potentials to be set in even bit lines and odd bit lines are generally slightly different from each other, but in the third embodiment, the potential setting that allows for this difference is not performed so that the number of potential tables can be reduced from two to one. Thus, the processing can be simpler in the third embodiment than in the first embodiment, enabling a cost reduction in mounting.

### Fourth Embodiment

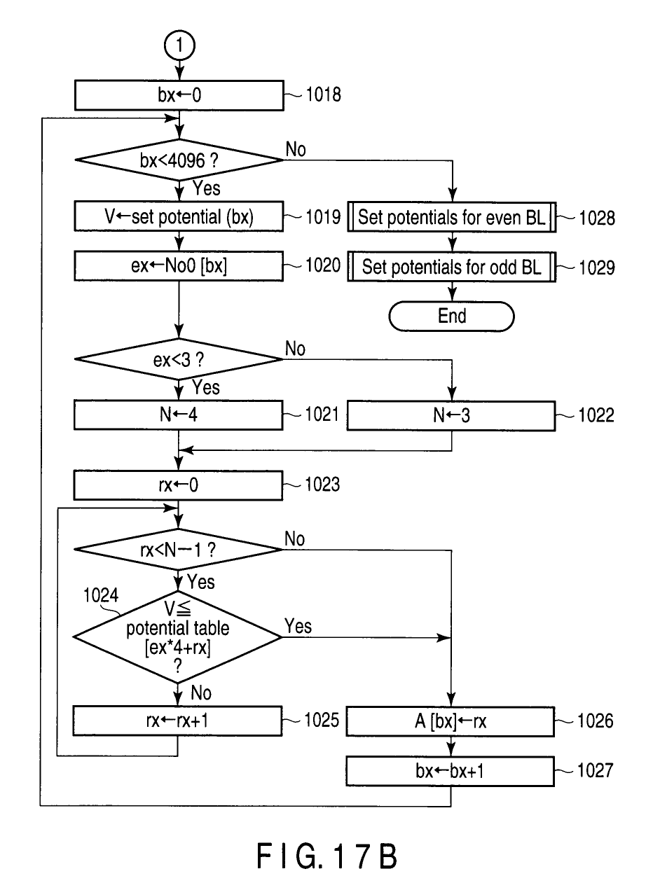

A fourth embodiment is different from the first embodiment in the configuration of the potential table which indicates the set potentials to be applied to the word line during writing. In the fourth embodiment, a fixed potential table prepared in advance is used instead of the two potential tables Te, To shown in FIG. 9A in the first embodiment. FIG. 16 is a flowchart showing processing for writing into a word line in the fourth embodiment.

The flowchart in FIG. 16 shows a procedure equal to the procedure in the flowchart in FIG. 14 shown in the third embodiment from which steps 801 to 810 for creating the potential table are removed. Moreover, the potential table in the fourth embodiment is recorded in the ROM within the control circuit 12, and the control circuit 12 has no potential table as a writable register.

The potential table prepared in the ROM in advance has 15 elements. Potential table [1] to potential table [15] are effective values. These values are provided by the following expression:

Potential table [rx]=(Vm*rx)/15

wherein a target potential corresponding to data “10(b)” in FIG. 10, that is, Exp[10(b)] is Vm.

Processing for calculating a set potential for the bit line BL(bx) in step 902 in FIG. 16 is the same as that in FIG. 15 described in the third embodiment.

As described above, according to the fourth embodiment, the potential table is stored in the ROM, so that the potential table creating processing shown in FIG. 9A in the first embodiment and in FIG. 14A in the third embodiment can be omitted. Thus, the write processing can be much simpler than in the first embodiment and the third embodiment. Moreover, there is no need to hold the potential table in the register, thus enabling a cost reduction in mounting.

Furthermore, in the fourth embodiment, setting several predetermined potentials for the word line is enough, so that the voltage generating circuit 13 shown in FIG. 2 does not need to perform A/D conversion, which enables a lower-cost circuit configuration.

### Fifth Embodiment

In a fifth embodiment, four kinds of potential tables are created for each data which is stored in the data register No0 and which is to be written in each memory cell. During write processing, a correction value for each potential table is only written to the correction value register A.

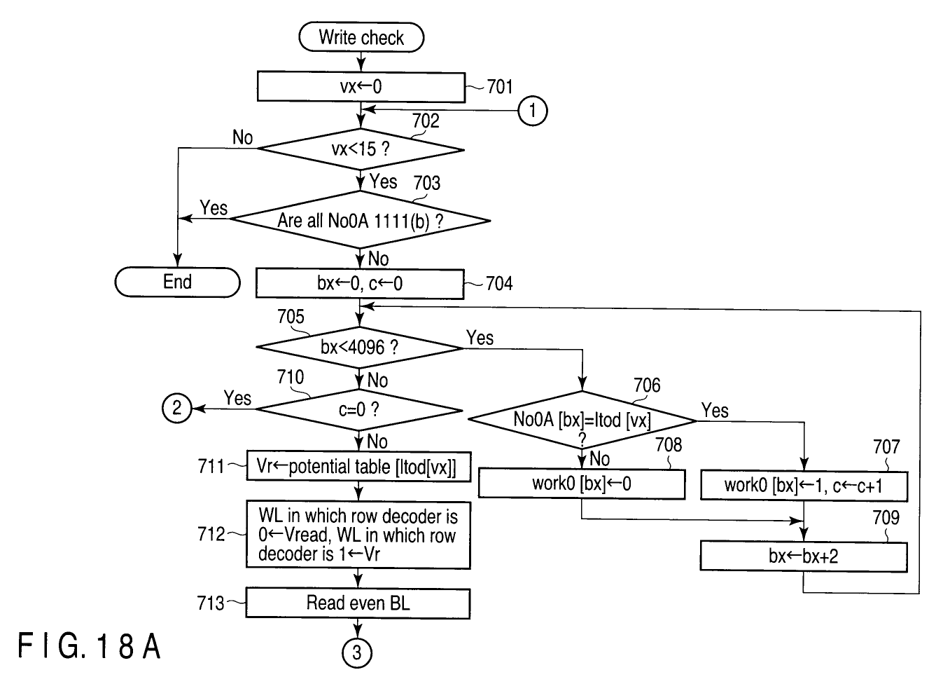

Details of processing for writing the data in the data register No0 to a word line indicated by “work_address-1” in step 309 of FIG. 6A are described. FIG. 17A and FIG. 17B are flowcharts showing processing performed by the control circuit 12 in step 309.

Data to be written to each memory cell is indicated by an internal variable ex. In the present embodiment, two bits are recorded in each memory cell, and ex is therefore a variable including 0 to 3 (00(b), 01(b), 10(b), 11(b)). First, the control circuit 12g initializes the internal variable ex to zero (step 1001). Then, the control circuit 12 sets 0 and Vread to internal variable_maximum value [ex] and minimum value [ex], respectively (steps 1002 to 1004).

Then, the control circuit 12 initializes the counter variable bx to zero (step 1005), and decides the maximum value and the minimum value while bx<4096. That is, the control circuit 12 calculates a set potential for the bit line BL(bx) and assigns the set potential to the internal variable V (step 1007). This processing is the same as that in FIG. 15. Further, the control circuit 12 sets the value of the data register No0 [bx] to the internal variable ex (step 1007). If V is less than the minimum value [ex], the control circuit 12 assigns V to the minimum value [ex] (step 1008). If V is beyond the maximum value [ex], the control circuit 12 assigns V to the maximum value [ex] (step 1009). Further, the control circuit 12 increases the counter variable bx by 1 (step 1010). Further, the control circuit 12 returns to the head of the loop, and performs similar processing until the counter variable bx reaches 4096.

Then, the control circuit 12 creates a potential table. The potential table has fifteen elements, and [0] to [14] have effective values. First, the control circuit 12 initializes the internal variable ex to zero (step 1011). If ex is less than 3, the control circuit 12 then sets 4 to an internal variable N (step 1012). If ex has reached 3, the control circuit 12 then sets 3 to the internal variable N (step 1013). Further, the control circuit 12 calculates “(maximum value [ex]−minimum value [ex])/N” to set an internal variable_interval (step 1014).

Then, the control circuit 12 initializes the internal variable rx to zero (step 1015). rx is a correction value stored in the correction value register A. Further, the control circuit 12 repeats the following calculating expression until rx reaches N to create a potential table [ex*4+rx] corresponding to the ex (steps 1016, 1017):

$$Potential table [ ex * 4 + rx ] = minimum value [ ex ] + interval * rx .$$

Then, the control circuit 12 returns to the head of the loop, and performs similar processing until the internal variable ex reaches 4. Thus, the potential table including the set potential for each ex is created.

In addition, as shown in step 1013, the correction value ranges from 0 to 2 only when ex is 3(11(b)). Therefore, no potential table [15] whereby “ex*4+rx” is 15 is created. This value 15(1111(b)) is used during a write check as a particular value which means no need for writing.

Then, the control circuit 12 searches the potential table for a correction value corresponding to the set potential for each memory cell, and writes the correction value to the correction value register A. First, the control circuit 12 initializes the counter variable bx to zero (step 1018). Further, the control circuit 12 calculates a set potential for the bit line BL(bx) and assigns the set potential to the internal variable V (step 1019). Moreover, the control circuit 12 sets data in the data register No0 [bx] to the internal variable ex (step 1020).

If ex is less than 3, the control circuit 12 then sets 4 to an internal variable N (step 1021). If ex has reached 3, the control circuit 12 then sets 3 to the internal variable N (step 1022). Further, the control circuit 12 initializes the internal variable rx to zero (step 1023). While increasing rx from 1 to “N−1” one by one, the control circuit 12 searches for rx whereby the value of the potential table [ex*4+rx] is equal to or more than V (step 1024). If such rx is found, the control circuit 12 sets the rx. If not, the control circuit 12 sets “N−1” to the correction value register A[bx] (step 1026). Further, the control circuit 12 increases bx by 1 (step 1027), and returns to the head of the loop, and then performs similar processing until the counter variable bx reaches 4096.

As a result of the processing described above, the potential table and the correction value of each memory cell are decided. Further, the control circuit 12 sets potentials for the even bit lines BL (step 1028). Further, the control circuit 12 sets potentials for the odd bit lines BL (step 1029).

The processing for setting potentials for the bit lines BL is basically the same as that in FIG. 11 described in the first embodiment. However, due to the change of the potential table and the value of No0A, the contents of step 603 in FIG. 11 are changed to “Are all No0A[bx] 1111(b)?” in the present embodiment.

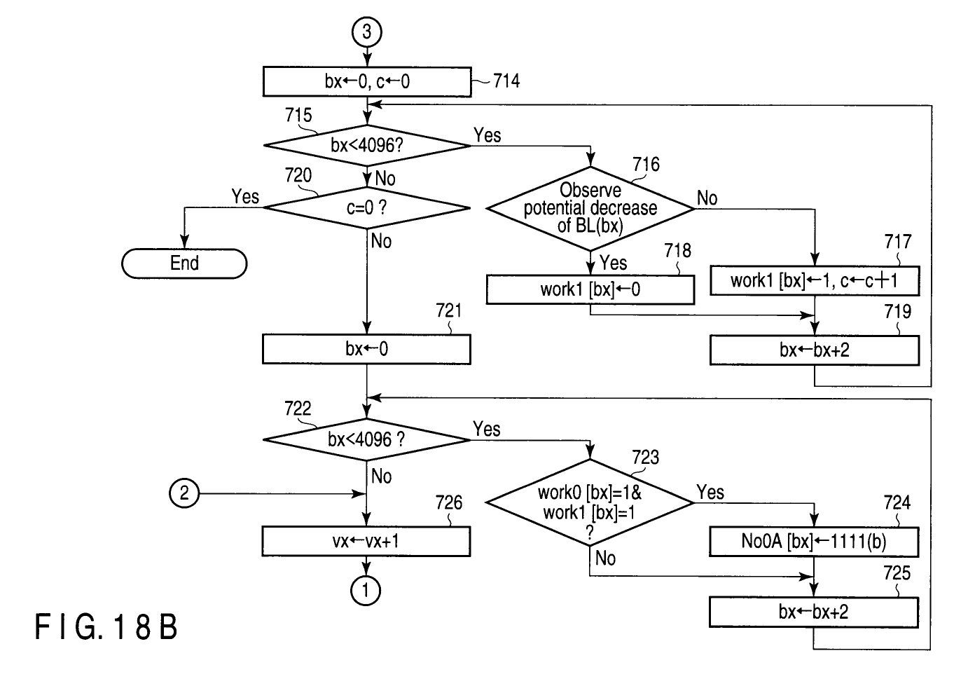

Next, details of the write check processing are described. FIGS. 18A and 18B are flowcharts showing the write check processing performed by the control circuit 12. This write check processing is basically the same as that in FIGS. 12A and 12B. In the following description, steps different from the steps in FIGS. 12A and 12B are mainly described.

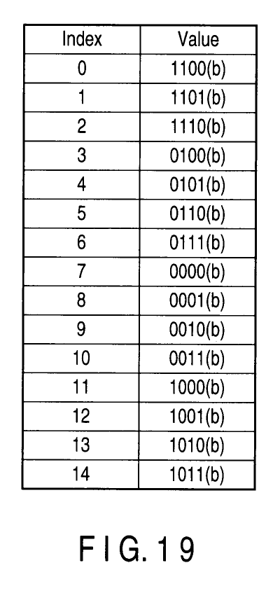

In the write check processing, the control circuit 12 first initializes the counter variable vx to zero (step 701). The counter variable vx is a variable for tracking the set potentials of the memory cells in ascending order. On the contrary, written data stored in the data register No0 are not arranged in the order of the set potentials. Therefore, the order of the set potentials is converted to the orders of the written data and their correction values by referring to a conversion table shown in FIG. 19. “Index” in the left side of FIG. 19 shows the value (set potential) indicated by the counter variable vx. “Value” in the right side shows the value of No0A, that is, written data in which upper two bits are stored in the data register No0 and a correction value in which lower two bits are stored in the correction value register A. In FIG. 19, the set potential increases as the index becomes higher.

Then, the control circuit 12 checks whether vx is below 15 (step 702). If vx has reached 15, the write check is finished. If vx is below 15, the control circuit 12 then checks whether No0A[bx] are 1111(b) for all even bx (step 703). If No0A[bx] are 1111(b) for all even bx, this means that there are no more memory cells that need to be set, thus the write check is finished.

If there is one or more bx in which No0A[bx] is not 1111(b), the control circuit 12 then checks whether there is No0A[bx] in which currently selected vx is the set potential. First, the control circuit 12 initializes the counter variables bx, c to zero (step 704).

If bx has not reached 4096 (step 705), the control circuit 12 checks whether No0A[bx] is equal to “1tod[vx]” (step 706). “1tod[vx]” indicates the corresponding “value” when vx in the conversion table shown in FIG. 19 is an index. If No0A[bx] is equal to “1tod[vx]”, the control circuit 12 sets 1 to the work register work0[bx], and increases the counter variable c by 1 (step 707). If No0A[bx] is not equal to “1tod[vx]”, the control circuit 12 sets zero to the work register work0[bx] (step 708). The control circuit 12 increases the counter variable bx by 2 in each case (step 709), and returns to step 705 to check whether bx has reached 4096.

When c is not zero in step 710, the control circuit 12 sets, to an internal variable Vr, a value obtained by searching a potential table [1tod[vx]] (step 711). This Vr serves to judge whether the potential of a memory cell has reached the read voltage Vr.

Furthermore, due to the change of the potential table and the value of No0A, the value to be set to No0A[bx] in step 724 is changed to “1111(b)”.

As described above in detail, in the fifth embodiment, the write data which is sent from the host device and stored in the data register No0 is saved as it is until the potential of the memory cell reaches a write target potential. Therefore, as shown in step 1019 of FIG. 17B, the value of the data register No0 at the moment has only to be referred to every time in calculating a correction value, thus leading to a simple algorithm.

It is also possible to apply the fourth embodiment to the fifth embodiment. This is achieved by the following method: The characteristics of the nonvolatile semiconductor memory device 1 are checked during manufacture, and the maximum value of decreases in the set potentials for each of the target potentials of FIG. 10 is found. A potential table is created so that the interval between the maximum value and the target potential is divided into three equal parts or four equal parts. Then, the potential table is stored in the ROM. According to this method, the advantage similar to that in the fourth embodiment can be obtained even in a configuration based on the fifth embodiment.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory device comprising:
a nonvolatile memory which includes a block having a plurality of memory cell groups, each of the memory cell groups being electrically connected to a plurality of bit lines and electrically connected to a common word line, each memory cell being recordable of a plurality of bits;
a first register which stores information obtained by correcting first data to be written to a first word line; and
a control circuit which sets a set potential in the first register and writes the bits to a write target first memory cell at a time using the information in the first register, the set potential being obtained by subtracting, from a target potential to be finally set in the first memory cell, a potential increase which is generated by setting a potential in an unwritten second memory cell adjacent to the first memory cell.

2. The device according to claim 1, further comprising a second register which stores second data to be written to a second word line following the first word line,
wherein the control circuit calculates the set potential based on information in the second register.

3. The device according to claim 1, wherein the potential increase is calculated by a value which is obtained by multiplying a target potential for the second memory cell by a constant based on a coupling effect between the first memory cell and the second memory cell.

4. The device according to claim 1, wherein the control circuit calculates a maximum value and a minimum value of set potentials of the first word line, divides a range between the maximum value and the minimum value into equal parts to generate a potential table, and uses the potential table to obtain the set potential.

5. The device according to claim 1, wherein
the control circuit calculates, for each write data, a correction value in accordance with the potential increase, generates a potential table by use of the write data and the correction value, and uses the potential table to obtain the set potential, and
the first register includes a first register portion which stores the first data and a second register portion which stores the correction value.

6. The device according to claim 1, wherein the control circuit holds a previously generated potential table which indicates a correspondence between write data and set potentials, and uses the potential table to obtain the set potential.

7. The device according to claim 1, wherein when writing a second command following a first command after having finished writing the first command, the control circuit starts writing with one or more word lines left from the last word line in which data has already been written.

8. The device according to claim 1, wherein the control circuit checks whether the first data has been written to the first word line in ascending order of set potentials, and omits write checks for set potentials which are not targeted for writing.

9. The device according to claim 8, wherein when a set potential to be checked is higher than potentials of all memory cells included in the first word line, the control circuit omits further write checks.

10. A nonvolatile semiconductor memory device comprising:
a nonvolatile memory which includes a block having a plurality of memory cell groups, each of the memory cell groups being electrically connected to a plurality of bit lines and electrically connected to a common word line, each memory cell being recordable of a plurality of bits;
a first register which stores information obtained by correcting first data to be written to a first word line; and
a control circuit which performs writing separately for even bit lines and odd bit lines, sets a set potential in the first register, and writes the bits to a write target first memory cell at a time using the information in the first register, the set potential being obtained by subtracting, from a target potential to be finally set in the first memory cell, a potential increase which is generated by setting a potential in an unwritten second memory cell adjacent to the first memory cell.

11. The device according to claim 10, further comprising a second register which stores second data to be written to a second word line following the first word line,
wherein the control circuit calculates the set potential based on information in the second register.

12. The device according to claim 10, wherein the potential increase is calculated by a value which is obtained by multiplying a target potential for the second memory cell by a constant based on a coupling effect between the first memory cell and the second memory cell.

13. The device according to claim 10, wherein the control circuit calculates a maximum value and a minimum value of set potentials of the word line, divides a range between the maximum value and the minimum value into equal parts to generate a potential table, and uses the potential table to obtain the set potential.

14. The device according to claim 13, wherein potential tables are generated for even bit lines and odd bit lines, respectively.

15. The device according to claim 10, wherein
the control circuit calculates, for each write data, a correction value in accordance with the potential increase, generates a potential table by use of the write data and the correction value, and uses the potential table to obtain the set potential, and
the first register includes a first register portion which stores the first data and a second register portion which stores the correction value.

16. The device according to claim 10, wherein the control circuit holds a previously generated potential table which indicates a correspondence between write data and set potentials, and uses the potential table to obtain the set potential.

17. The device according to claim 10, wherein when writing a second command following a first command after having finished writing the first command, the control circuit starts writing with one or more word lines left from the last word line in which data has already been written.

18. The device according to claim 10, wherein the control circuit checks whether the first data has been written to the first word line in ascending order of set potentials, and omits write checks for set potentials which are not targeted for writing.

19. The device according to claim 18, wherein when a set potential to be checked is higher than potentials of all memory cells included in the first word line, the control circuit omits further write checks.
